(19) United States
(12) Patent Application Publication
(10) Pub. No.: US 2023/0174702 A1
(43) Pub. Date: Jun. 8, 2023

(54) VERTICALLY PHASE-SEPARATED LAYER OF A BLOCK COPOLYMER

(71) Applicant: NISSAN CHEMICAL CORPORATION, Tokyo (JP)

(72) Inventors: Ryuta MIZUOCHI, Toyama-shi (JP); Mamoru TAMURA, Toyama-shi (JP); Makoto NAKAJIMA, Toyama-shi (JP); Rikimaru SAKAMOTO, Toyama-shi (JP)

(73) Assignee: NISSAN CHEMICAL CORPORATION, Tokyo (JP)

(21) Appl. No.: 17/923,774

(22) PCT Filed: May 25, 2021
(86) PCT No.: PCT/JP2021/019852

§ 371 Date: Nov. 7, 2022

(30) Foreign Application Priority Data
May 26, 2020 (JP) 2020-091721
Aug. 5, 2020 (JP) 2020-133320

(51) Int. Cl. C08F 299/02; C08F 299/08; H01L 21/308; H01L 21/311; H01L 21/3065

(52) U.S. Cl. CPC C08F 299/024; C08F 299/08; H01L 21/3081; H01L 21/3086; H01L 21/31138; H01L 21/3065

(57) ABSTRACT

A layer including a block copolymer in which a microphase-separated structure of the block copolymer has been induced perpendicular to a substrate, this process being difficult in heating under atmospheric pressure; a method for producing the layer; and a method for producing a semiconductor device in which is used a vertically phase-separated layer of a block copolymer. A vertically phase-separated layer of a block copolymer formed by heating at a pressure below atmospheric pressure and a temperature at which induced self-assembly can occur.

### FIELD OF INVENTION

The present invention relates to a vertically phase-separated layer of a block copolymer (for example, diblock copolymer layer, triblock copolymer layer, or tetrablock copolymer layer), preferably a layer comprising vertically phase-separated polystyrene-block (hereinafter, abbreviated to “b”)-polymethyl methacrylate (PS-b-PMMA) using a self-assembly technique for a block copolymer in the field of semiconductor lithography, a method for producing the layer, and a method for producing a semiconductor device using the vertically phase-separated layer of a block copolymer, preferably PS-b-PMMA layer.

### BACKGROUND ART

In recent years, as large scale integrated circuits (LSIs) have been further scaled down, techniques for fabrication of ultrafine microstructures are demanded. For meeting such demands, a pattern forming technique for forming micro-patterns utilizing a phase-separated structure formed by self-organization (or self-assembly) of a block copolymer, in which polymers incompatible with each other are allowed to bond together, is being put into practical use. For example, a method for forming a pattern has been proposed, in which a self-assembled film comprising a block copolymer containing two or more polymers bonded to each other is formed on the surface of a substrate, the block copolymer in the self-assembled film is allowed to cause phase separation, and a phase of at least one polymer of the polymers constituting the block copolymer is selectively removed. Patent Literature 1 discloses an underlayer film-forming composition for a self-organized (or self-assembled) film comprising a polycyclic aromatic vinyl compound. Non-Patent Literature 1 discloses a technique, in which directed self-assembly of a self-assembled film is caused by reducing the oxygen concentration in the atmosphere.

### CITATION LIST

### Patent Literature

Patent Literature 1: WO 2014/097993 A1

### Non-Patent Literature

Non-Patent Literature 1: Nathalie Frolet et al., “Expanding DSA process window with atmospheric control”, Proc. of SPIE Vol. 11326 113261J-1 to J-6 (2020)

### SUMMARY OF INVENTION

### Technical Problem

An object of the present invention is to provide a layer comprising a block copolymer, preferably PS-b-PMMA, in which a micro-phase-separated structure of the block copolymer, preferably PS-b-PMMA, which is difficult to obtain by heating under atmospheric pressure, has been induced vertically with respect to a substrate without causing defective orientation; a method for producing the layer; and a method for producing a semiconductor device using the vertically phase-separated block copolymer (preferably PS-b-PMMA) layer.

### Solution to Problem

The present invention encompasses the followings.

[1]

A vertically phase-separated layer of a block copolymer formed by heating the block copolymer at a temperature capable of causing directed self-assembly under a pressure lower than atmospheric pressure.

[2]

The layer of the block copolymer according to item [1], wherein the block copolymer is PS-b-PMMA.

[3]

The vertically phase-separated layer of a block copolymer according to item [1] or [2], wherein the vertically phase-separated layer comprises a cylinder shape portion.

[4]

The vertically phase-separated layer of a block copolymer according to item [3], wherein the cylinder shape portion comprises PMMA.

[5]

The vertically phase-separated layer of a block copolymer according to any one of items [1] to [4], wherein the heating temperature is 270° C. or higher.

[6]

The vertically phase-separated layer of a block copolymer according to any one of items [1] to [5], which further has a neutralizing layer for neutralizing a surface energy of the block copolymer under the layer of the block copolymer.

[7]

The vertically phase-separated layer of a block copolymer according to item [6], wherein the neutralizing layer comprises a polymer having an aromatic compound-derived unit structure.

[8]

The vertically phase-separated layer of a block copolymer according to item [7], wherein the polymer in the neutralizing layer contains the aromatic compound-derived unit structure in a proportion of 50% by mole or more.

[9]

The vertically phase-separated layer of a block copolymer according to item [6], wherein the neutralizing layer comprises a polymer having a unit structure comprising an aliphatic polycyclic structure of an aliphatic polycyclic compound in a principal chain.

[10]

The vertically phase-separated layer of a block copolymer according to item [6], wherein the neutralizing layer comprises a polysiloxane.

[11]

The vertically phase-separated layer of a block copolymer according to any one of items [6] to [8], wherein the neutralizing layer comprises a polymer having a reactive substituent at a terminal thereof.

[12]

The vertically phase-separated layer of a block copolymer according to any one of items [1] to [10], which is formed above a substrate.

[13]

A method for producing a vertically phase-separated layer of a block copolymer, comprising the steps of:

forming a block copolymer layer above a substrate; and then

heating the substrate under a pressure lower than atmospheric pressure.

[14]

A method for producing a semiconductor device, comprising the steps of:

forming a block copolymer layer above a substrate;

heating the substrate under a pressure lower than atmospheric pressure;

subjecting the vertically phase-separated layer of a block copolymer to etching;

and

subjecting the substrate to etching.

### Advantageous Effects of Invention

The vertically phase-separated layer of a block copolymer, preferably

PS-b-PMMA layer, of the present invention is a vertically phase-separated layer of a block copolymer, preferably PS-b-PMMA layer (which may be a layer comprising PS-b-PMMA but is preferably a layer comprising only PS-b-PMMA), wherein the vertically phase-separated layer of the block copolymer is formed by heating the block copolymer layer, preferably PS-b-PMMA layer, to be phase-separated, under a pressure lower than atmospheric pressure, so that the block copolymer, preferably PS-b-PMMA, undergoes directed self-assembly and a micro-phase-separated structure is vertically induced with respect to a substrate; and is preferably the layer of the block copolymer, preferably PS-b-PMMA layer, having at least a cylinder shape (i.e., which may contain one or more cylinder shapes); preferably the layer of the block copolymer, preferably PS-b-PMMA layer, having a cylinder shape. The vertically phase-separated layer of a block copolymer, preferably PS-b-PMMA-containing layer, is selectively subjected to etching treatment to process the semiconductor substrate, producing a semiconductor device.

### BRIEF DESCRIPTION OF DRAWINGS

FIG. 1 Schematic view showing the PS-b-PMMA directed self-assembly.

FIG. 2 Schematic view showing a substrate, an underlayer film layer (corresponding to the neutralizing layer in the present invention), and a self-assembled layer (corresponding to the PS-b-PMMA layer in the present invention).

FIG. 3 Electron photomicrographs showing examples of the “vertical orientation” and “defective orientation” in the description.

### DESCRIPTION OF EMBODIMENTS

<Vertically Phase-Separated Layer of a Block Copolymer>

The vertically phase-separated layer of a block copolymer, preferably PS-b-PMMA layer, of the present invention may be formed by applying a block copolymer layer-forming composition containing a known block copolymer layer, preferably PS-b-PMMA, preferably a PS-b-PMMA layer-forming composition, onto a substrate, and heating the applied composition under a pressure lower than atmospheric pressure.

The vertical phase separation has to occur at least in part of the layer of the block copolymer, preferably PS-b-PMMA layer; however, it is preferred that the vertical phase separation occurs over the whole of the layer of the block copolymer, preferably PS-b-PMMA layer (the vertically phase-separated area is 80% or more, more preferably 90% or more, further preferably 95% or more, most preferably 100%, based on the whole area onto which the layer of the block copolymer, preferably PS-b-PMMA layer, is applied). The vertically phase-separated area can be determined from an average of vertically phase-separated areas in the image of observation obtained from the results of the observation under an electron microscope from three or more sites of part of the upper surface of the substrate after the phase separation step. As seen in the examples of the electron photomicrographs of FIG. 3, the layer of the block copolymer can be judged to have defective orientation, if there is a portion of defective orientation in the image of observation obtained from the results of the observation under an electron microscope from the upper surface of part of the surface of the substrate after the phase separation step.

PS-b-PMMA, which is a diblock copolymer, may be produced by a known method. A commercially available product of PS-b-PMMA may also be used.

Further, the block copolymer may be a block copolymer, in which a polymer containing no silicon and having styrene optionally substituted with an organic group or a derivative thereof as a constituent unit, or a polymer containing no silicon and having a lactide-derived structure as a constituent unit and a silicon-containing polymer having styrene substituted with a silicon-containing group as a constituent unit are bonded to each other.

Of these, a combination of a silylated polystyrene derivative and a polystyrene derivative polymer or a combination of a silylated polystyrene derivative polymer and a polylactide is preferred.

Of these, a combination of a silylated polystyrene derivative having a substituent at the 4-position and a polystyrene derivative polymer having a substituent at the 4-position, or a combination of a silylated polystyrene derivative polymer having a substituent at the 4-position and a polylactide is preferred.

More preferred specific examples of block copolymers include a combination of poly(trimethylsilylstyrene) and polymethoxystyrene, a combination of polystyrene and poly(trimethylsilylstyrene), and a combination of poly(trimethylsilylstyrene) and poly(D,L-lactide).

More preferred specific examples of block copolymers include a combination of poly(4-trimethylsilylstyrene) and poly(4-methoxystyrene), a combination of polystyrene and poly(4-trimethylsilylstyrene), and a combination of poly(4-trimethylsilylstyrene) and poly(D,L-lactide).

Most preferred specific examples of block copolymers include a poly(4-methoxystyrene)/poly(4-trimethylsilylstyrene) copolymer and a polystyrene/poly(4-trimethylsilylstyrene) copolymer.

The entire disclosure of WO 2018/135456 A1 is incorporated in the present description by reference.

Further, the block copolymer may be a block copolymer, in which a polymer containing no silicon and a silicon-containing polymer having styrene substituted with a silicon-containing group as a constituent unit are bonded to each other, wherein the polymer containing no silicon has a unit structure represented by the following formula (1-1c) or (1-2c):

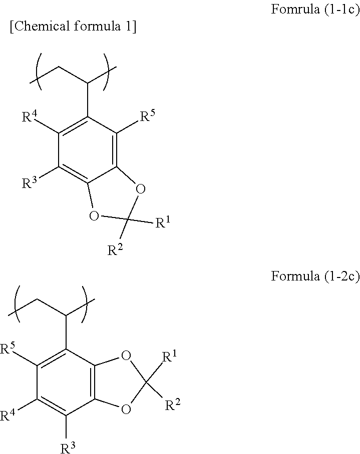

wherein each of R¹ and R² independently represents a hydrogen atom, a halogen atom, or an alkyl group having 1 to 10 carbon atoms, and each of R³ to R⁵ independently represents a hydrogen atom, a hydroxy group, a halogen atom, an alkyl group having 1 to 10 carbon atoms, an alkoxy group having 1 to 10 carbon atoms, a cyano group, an amino group, an amide group, or a carbonyl group.

The silicon-containing group may be one which contains one silicon atom.

The silicon-containing polymer may be one which has a unit structure represented by the following formula (2c):

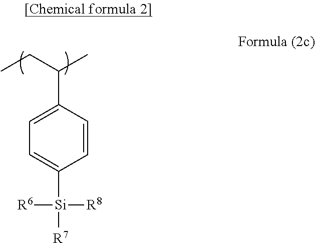

wherein each of R⁶ to R⁸ independently represents an alkyl group having 1 to 10 carbon atoms or an aryl group having 6 to 40 carbon atoms.

Furthermore, as the block copolymer, any of the block copolymers disclosed in JP 2019-507815 A may be used, including the following [BCP1] to [BCP4].

[BCP1] A block copolymer, which comprises 5-vinylbenzo[d][1,3]dioxole.

[BCP2] The block copolymer according to [BCP1], which further comprises a block containing silicon.

[BCP3] The block copolymer according to [BCP2], which further comprises pentamethyldisilylstyrene.

[BCP4] The block copolymer according to [BCP3], which is poly(5-vinylbenzo[d][1,3]dioxole)-b-poly(pentamethyldisilylstyrene).

A synthesis of the above-mentioned poly(5-vinylbenzo[d][1,3]dioxole-block-4-pentamethyldisilylstyrene) is shown in Scheme 1 below.

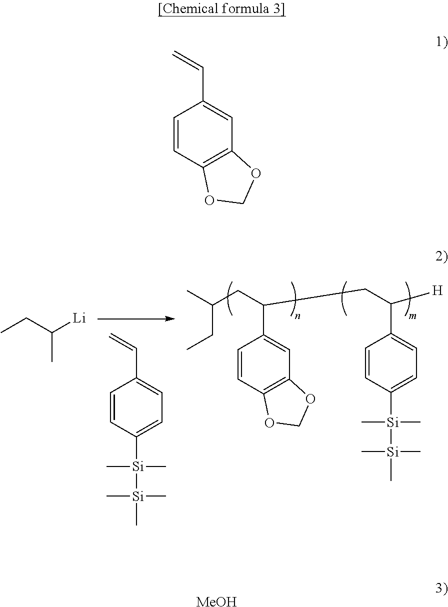

The silicon-containing polymer or block containing silicon is preferably poly(4-trimethylsilylstyrene) derived from 4-trimethylsilylstyrene. The silicon-containing polymer or block containing silicon is preferably poly(pentamethyldisilylstyrene) derived from pentamethyldisilylstyrene. The aryl group having 6 to 40 carbon atoms means a monocyclic or polycyclic, monovalent aromatic hydrocarbon group having 6 to 40 carbon atoms, and specific examples thereof include a phenyl group, a naphthyl group, and an anthryl group. The entire disclosure of WO 2020/017494 A1 is incorporated in the present description by reference.

Further, a block copolymer comprising a combination of the monomers shown below may be used: styrene, methyl methacrylate, dimethylsiloxane, propylene oxide, ethylene oxide, vinylpyridine, vinylnaphthalene, D,L-lactide, methoxystyrene, methylenedioxystyrene, trimethylsilylstyrene, and pentamethyldisilylstyrene.

The useful block copolymer has at least two blocks, and may be a copolymer having different blocks, such as a diblock, triblock, or tetrablock copolymer, and each block may be a homopolymer or a random or alternating copolymer.

Examples of typical block copolymers include polystyrene-b-polyvinylpyridine, polystyrene-b-polybutadiene, polystyrene-b-polyisoprene, polystyrene-b-polymethyl methacrylate, polystyrene-b-polyalkenyl aromatic, polyisoprene-b-polyethylene oxide, polystyrene-b-poly(ethylene-propylene), polyethylene oxide-b-polycaprolactone, polybutadiene-b-polyethylene oxide, polystyrene-b-poly(t-butyl (meth)acrylate), polymethyl methacrylate-b-poly(t-butyl methacrylate), polyethylene oxide-b-polypropylene oxide, polystyrene-b-polytetrahydrofuran, polystyrene-b-polyisoprene-b-polyethylene oxide, poly(styrene-b-dimethylsiloxane), poly(methyl methacrylate-b-dimethylsiloxane), poly(methyl (meth)acrylate-r-styrene)-b-polymethyl methacrylate, poly(methyl (meth)acrylate-r-styrene)-b-polystyrene, poly(p-hydroxystyrene-r-styrene)-b-polymethyl methacrylate, poly(p-hydroxystyrene-r-styrene)-b-polyethylene oxide, polyisoprene-b-polystyrene-b-polyferrocenylsilane, and a combination containing at least one member of the above-mentioned block copolymers.

Further examples include block copolymers comprising a combination of the below-mentioned organic polymers and/or metal-containing polymers.

Examples of typical organic polymers include poly(9,9-bis(6′-N,N,N-trimethylammonium)-hexyl)-fluorenephenylene) (PEP), poly(4-vinylpyridine) (4PVP), hydroxypropylmethyl cellulose (HPMC), polyethylene glycol (PEG), a poly(ethylene oxide)-poly(propylene oxide) diblock or multiblock copolymer, polyvinyl alcohol (PVA), poly(ethylene-vinyl alcohol) (PEVA), polyacrylic acid (PAA), polylactic acid (PLA), poly(ethyloxazoline), poly(alkyl acrylate), polyacrylamide, poly(N-alkylacrylamide), poly(N,N-dialkylacrylamide), polypropylene glycol (PPG), polypropylene oxide (PPO), partially or wholly hydrogenated poly(vinyl alcohol), dextran, polystyrene (PS), polyethylene (PE), polypropylene (PP), polyisoprene (PI), polychloroprene (CR), polyvinyl ether (PVE), polyvinyl acetate (PVA), polyvinyl chloride (PVC), polyurethane (PU), polyacrylate, polymethacrylate, oligosaccharide, and polysaccharide, although the organic polymer is not limited to these polymers.

Examples of metal-containing polymers include silicon-containing polymers, such as polydimethylsiloxane (PDMS), cage silsesquioxane (POSS), and poly(trimethylsilylstyrene) (PTMSS), and polymers containing silicon and iron, such as poly(ferrocenyldimethylsilane) (PFS), although the metal-containing polymer is not limited to these polymers.

Examples of typical block copolymers include diblock copolymers, such as polystyrene-b-polydimethylsiloxane (PS-PDMS), poly(2-vinylpropylene)-b-polydimethylsiloxane (P2VP-PDMS), polystyrene-b-poly(ferrocenyldimethylsilane) (PS-PFS), and polystyrene-b-poly-DL-polylactic acid (PS-PLA), and triblock copolymers, such as polystyrene-b-poly(ferrocenyldimethylsilane)-b-poly(2-vinylpyridine) (PS-PFS-P2VP), polyisoprene-b-polystyrene-b-poly(ferrocenyldimethylsilane) (PI-PS-PFS), and polystyrene-b-poly(ferrocenyldimethylsilane)-b-polystyrene (PS-PTMSS-PS), although the block copolymer is not limited to these copolymers. In an Example, the PS-PTMSS-PS block copolymer contains a poly(trimethylsilylstyrene) polymer block comprising two PTMSS chains linked through a linker having four styrene units. For example, such a modified type of block copolymer as disclosed in the specification of U.S. Patent Application Publication No. 2012/0046415 may also be considered.

Examples of the other block copolymers include a block copolymer, in which a polymer having styrene or a derivative thereof as a constituent unit and a polymer having (a)an (meth)acrylate as a constituent unit are bonded to each other; a block copolymer, in which a polymer having styrene or a derivative thereof as a constituent unit and a polymer having siloxane or a derivative thereof as a constituent unit are bonded to each other; and a block copolymer, in which a polymer having an alkylene oxide as a constituent unit and a polymer having (a)an (meth)acrylate as a constituent unit are bonded to each other. The term “(meth)acrylate” means one or both of an acrylate having a hydrogen atom bonded at the α-position and a methacrylate having a methyl group bonded at the α-position.

Examples of (meth)acrylates include (meth)acrylic acid having bonded to the carbon atom thereof a substituent, such as an alkyl group or a hydroxyalkyl group. Examples of alkyl groups used as a substituent include linear, branched, or cyclic alkyl groups having 1 to 10 carbon atoms. Specific examples of (meth)acrylates include methyl (meth)acrylate, ethyl (meth)acrylate, propyl (meth)acrylate, cyclohexyl (meth)acrylate, octyl (meth)acrylate, nonyl (meth)acrylate, hydroxyethyl (meth)acrylate, hydroxypropyl (meth)acrylate, benzyl (meth)acrylate, anthracene (meth)acrylate, glycidyl (meth)acrylate, 3,4-epoxycyclohexylmethane (meth)acrylate, and propyltrimethoxysilane (meth)acrylate.

Examples of derivatives of styrene include α-methylstyrene, 2-methylstyrene, 3-methyl styrene, 4-methyl styrene, 4-t-butyl styrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

Examples of derivatives of siloxane include dimethylsiloxane, diethylsiloxane, diphenylsiloxane, and methylphenylsiloxane.

Examples of alkylene oxides include ethylene oxide, propylene oxide, isopropylene oxide, and butylene oxide.

Examples of the block copolymers include a styrene-polyethyl methacrylate block copolymer, a styrene-(poly-t-butyl methacrylate) block copolymer, a styrene-polymethacrylic acid block copolymer, a styrene-polymethyl acrylate block copolymer, a styrene-polyethyl acrylate block copolymer, a styrene-(poly-t-butyl acrylate) block copolymer, and a styrene-polyacrylic acid block copolymer.

With respect to a method for synthesizing a block copolymer, a block copolymer may be obtained by living radical polymerization, living cationic polymerization, or living anionic polymerization, of which the polymerization process consists of an initiation reaction and a propagation reaction, and which is free from any side reaction that would deactivate the propagation end. The propagation end can continue a propagation activating reaction during the polymerization reaction. By inhibiting chain transfer, polymer (A) having a uniform length may be obtained. When another monomer (b) is added, polymerization would proceed using the propagation end of polymer (A) in the presence of monomer (b), to form a block copolymer (AB).

For example, when two types of blocks, i.e., blocks A and B are present, the molar ratio of polymer chain (A) and polymer chain (B) may be 1:9 to 9:1, preferably 3:7 to 7:3.

The volume ratio of the block copolymer used in the present invention is, for example, 30:70 to 70:30. Homopolymer A or B is a polymerizable compound having at least one radically polymerizable reactive group (vinyl group or vinyl group-containing organic group).

The weight average molecular weight Mw of the block copolymer used in the present invention is within the range of preferably 1,000 to 100,000, or 5,000 to 100,000. When the weight average molecular weight Mw of the block copolymer is less than 1,000, the application properties to a substrate are likely to be poor, and, when the weight average molecular weight Mw of the block copolymer is 100,000 or more, the solubility of the block copolymer in a solvent is likely to be poor.

The polydisperse degree (Mw/Mn) of the block copolymer in the present invention is within the range of preferably 1.00 to 1.50, especially preferably 1.00 to 1.20.

In an embodiment of the present invention, the block copolymer is PS-b-PMMA.

The layer of the block copolymer-forming composition (preferably PS-b-PMMA layer-forming composition) in the present invention may have a solid content within the range of 0.1 to 10% by mass, or 0.1 to 5% by mass, or 0.1 to 3% by mass. The solid content refers to a content of the solids remaining after removing the solvent from the layer of the block copolymer-forming composition (preferably PS-b-PMMA layer-forming composition).

The proportion of the block copolymer in the solids of the composition may be within the range of 30 to 100% by mass, or 50 to 100% by mass, or 50 to 90% by mass, or 50 to 80% by mass.

<Solvent>

With respect to the solvent contained in the layer of the block copolymer-forming composition, preferably PS-b-PMMA layer-forming composition, in the present invention, there is no particular limitation as long as it is a solvent capable of dissolving therein the block copolymer, preferably PS-b-PMMA, but preferred is an organic solvent used in a semiconductor lithography process. Specific examples of organic solvents include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. These solvents may be used each alone or in combination of two or more.

Of these solvents, preferred are propylene glycol monomethyl ether, propylene glycol monomethyl ether acetate, ethyl lactate, butyl lactate, butyl acetate, methyl isobutyl ketone, and cyclohexanone. Particularly, propylene glycol monomethyl ether and propylene glycol monomethyl ether acetate are preferred.

Further, the solvent contained in the layer of the block copolymer-forming composition, preferably PS-b-PMMA layer-forming composition, may be a combination of a low boiling-point solvent (A) having a boiling point of 160° C. or lower and a high boiling-point solvent (B) having a boiling point of 170° C. or higher, which is disclosed in WO 2018/135456 A1.

The high boiling-point solvent (B) may be contained in an amount of 0.3 to 2.0% by weight, based on the total weight of the solvents contained in the composition.

The low boiling-point solvent (A) having a boiling point of 160° C. or lower is preferably, for example, propylene glycol monomethyl ether acetate (boiling point: 146° C.), n-butyl acetate (boiling point: 126° C.), or methyl isobutyl ketone (boiling point: 116° C.).

The high boiling-point solvent (B) having a boiling point of 170° C. or higher is preferably, for example, N-methylpyrrolidone (boiling point: 204° C.), diethylene glycol monomethyl ether (boiling point: 193° C.), N,N-dimethylisobutylamide (boiling point: 175° C.), 3-methoxy-N,N-dimethylpropaneamide (boiling point: 215° C.), or γ-butyrolactone (boiling point: 204° C.).

With respect to each of the low boiling-point solvent (A) and high boiling-point solvent (B), two or more solvents may be selected and used in combination. In a preferred embodiment, the high boiling-point solvent (B) is contained in an amount of 0.3 to 2.0% by weight, based on the total weight of the solvents contained in the composition. The high boiling-point solvent (B) is most preferably contained in an amount of 0.5 to 1.5% by weight.

The atmospheric pressure refers to 760,000 mTorr. With respect to the pressure lower than atmospheric pressure, there is no particular limitation as long as the pressure is lower than 760,000 mTorr; however, the pressure is preferably, for example, 500,000 mTorr or less, 300,000 mTorr or less, 100,000 mTorr or less, 50,000 mTorr or less, 30,000 mTorr or less, 20,000 mTorr or less, 10,000 mTorr or less, 9,000 mTorr or less, 8,000 mTorr or less, 7,000 mTorr or less, 6,000 mTorr or less, 5,000 mTorr or less, 4,000 mTorr or less, 3,000 mTorr or less, 2,000 mTorr or less, 1,000 mTorr or less, 900 mTorr or less, or 800 mTorr or less. For example, the pressure is within the range of preferably 10,000 to 10 mTorr, 1,000 to 50 mTorr, or 800 to 50 mTorr.

With respect to the gas contained in the atmosphere under a pressure lower than atmospheric pressure (the atmosphere for directed self-assembly of the block copolymer, preferably PS-b-PMMA), there is no particular limitation. The gas contained in the atmosphere may be air, an N₂/O₂ mixed gas (in any mixing ratio), an N₂ simple gas, or an O₂ simple gas. Another gas that would not adversely affect directed self-assembly (vertical phase separation) of the block copolymer, preferably PS-b-PMMA, may be contained in the atmosphere.

The heating refers to a heating treatment conducted relative to a film formed by applying a composition containing the block copolymer, preferably PS-b-PMMA, onto the surface of a semiconductor substrate (such as a silicon wafer) which is generally in a flat plate form and described below in detail. The heating is conducted at a temperature capable of causing directed self-assembly. The heating temperature is generally within the range of 230 to 350° C., but is preferably 270° C. or higher. In another embodiment, the heating temperature is within the range of preferably 260 to 340° C., 270 to 330° C., or 270 to 320° C. The heating time is within the range of generally one minute to one hour, but may be within the range of 2 to 30 minutes or 3 to 10 minutes.

For example, at an elevated temperature of 300° C. or higher (300 to 330° C.), vertical phase separation may be made in a time as relatively short as 1 to 10 minutes, 1 to 5 minutes, or 1 to 3 minutes.

It is preferred that the vertical phase separation contains a cylinder shape portion. The cylinder shape is also called a cylindrical shape, and is a portion in which, among the blocks of the block copolymer, those having a smaller weight average molecular weight have undergone self-assembly (self-organization).

In the PS-b-PMMA, with respect to the weight average molecular weight of each of PS and PMMA, for example, PS has a weight average molecular weight in the range of from 20,000 to 100,000, and PMMA has a weight average molecular weight in the range of from 5,000 to 50,000. It is preferred to use a PS having a large weight average molecular weight as compared to PMMA. The ratio of the weight average molecular weight of PS to that of PMMA (PS/PMMA ratio) is, for example, within the range of 20.0 to 1.1, 10.0 to 1.1, 5.0 to 1.1, or 3.0 to 1.1.

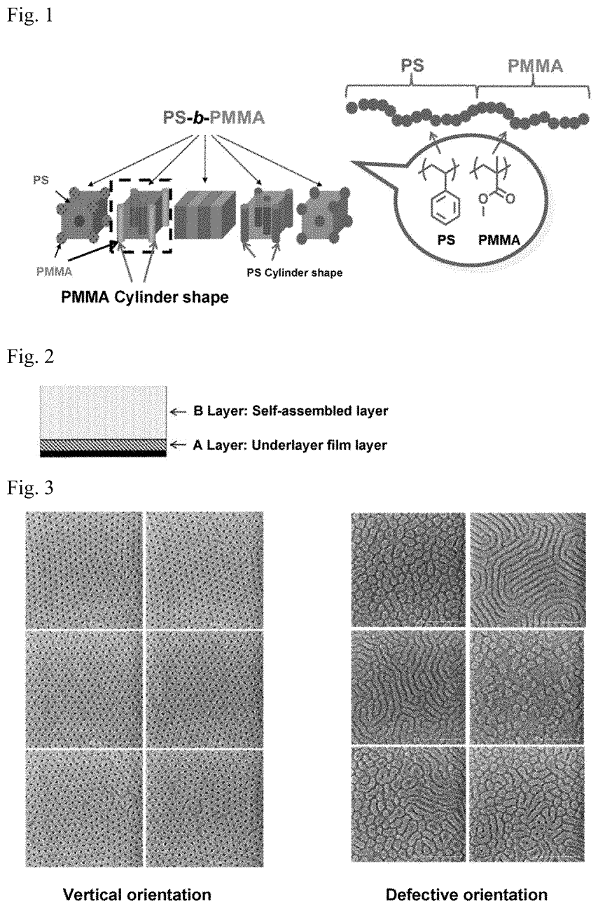

The cylinder shape portion may comprise any one of PS and PMMA, although it preferably comprises PMMA. When the PS has a higher weight average molecular weight than the PMMA as mentioned above, a vertically phase-separated structure is formed in such a manner that the PMMA undergoes self-assembly in a cylinder shape, the PS undergoes self-assembly around the PMMA, and the PMMA cylinders are present to be scattered. FIG. 1 shows the schematic views. In FIG. 1, the cylindrical shapes pointed by the arrows drawn from the letters PMMA indicate the cylinder portion in the present invention.

It is preferred to further provide a neutralizing layer for neutralizing the surface energy of the layer of the block copolymer, preferably PS-b-PMMA, under the layer of the block copolymer, preferably PS-b-PMMA layer.

Neutralization of the surface energy means controlling the surface energy for vertical phase separation of the block copolymer so that the surface energy of the whole block copolymer having a hydrophilic portion (for example, PMMA) and a hydrophobic portion (for example, PS) and the surface energy of the surface of, e.g., a substrate in contact with the block copolymer are close to or equivalent to each other. When the above-mentioned surface energies are close to or equivalent to each other, a vertically phase-separated structure is formed. Therefore, generally, for achieving vertical phase separation of the layer of the block copolymer, preferably PS-b-PMMA layer, a neutralizing layer for neutralizing the surface energy is formed on the surface of a substrate (i.e., under the layer of the block copolymer, preferably PS-b-PMMA layer) to neutralize the surface energy, but, when the surface energy of the surface of the substrate is preliminarily equivalent to or close to the surface energy of the whole block copolymer, there is no need to form a neutralizing layer. This theory is described in, for example, Macromolecules 2006, 39, 2449-2451.

The neutralizing layer may comprise a polymer having an aromatic compound-derived unit structure.

The aromatic compound preferably contains an aryl group having 6 to 40 carbon atoms.

Examples of the aryl groups having 6 to 40 carbon atoms include a phenyl group, an o-methylphenyl group, a m-methylphenyl group, a p-methylphenyl group, an o-chlorophenyl group, a m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, a m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group. Of these, the aromatic compound preferably contains a phenyl group, an α-naphthyl group (=1-naphthyl group), or a β-naphthyl group (=2-naphthyl group).

The α-naphthyl group (=1-naphthyl group) or β-naphthyl group (=2-naphthyl group) is preferably contained in an amount of 40% by mole or more, 45% by mole or more, 50% by mole or more, 60% by mole or more, 70% by mole or more, or 80% by mole or more, relative to the entirety of the polymer. The upper limit of the amount is, for example, 95% by mole, or 90% by mole.

The polymer may be a polymer derived from, for example, 1-vinylnaphthalene, 2-vinylnaphthalene, or benzyl methacrylate. The polymer may be preferably a polymer derived from 2-vinylnaphthalene or benzyl methacrylate.

The polymer preferably contains the aromatic compound-derived unit structure in an amount of 50% by mole or more, relative to the entirety of the polymer. The polymer further preferably contains the aromatic compound-derived unit structure in an amount of, for example, 50 to 99% by mole, 55 to 99% by mole, 60 to 99% by mole, 65 to 99% by mole, 70 to 99% by mole, 75 to 99% by mole, 80 to 99% by mole, 81 to 99% by mole, 82 to 98% by mole, 83 to 97% by mole, 84 to 96% by mole, or 85 to 95% by mole, relative to the entirety of the polymer.

The neutralizing layer may be a neutralizing layer derived from the underlayer film-forming composition for a self-assembled film described in the specification of WO 2014/097993 A1.

The neutralizing layer may comprise a polymer having a polycyclic aromatic vinyl compound-derived unit structure. The neutralizing layer may comprise the polymer having a unit structure of a polycyclic aromatic vinyl compound in an amount of 0.2% by mole or more, based on the mole of the whole unit structure of the polymer.

The polymer may be a polymer which has a unit structure of an aromatic vinyl compound in an amount of 20% by mole or more, based on the mole of the whole unit structure of the polymer, and which has a unit structure of a polycyclic aromatic vinyl compound in an amount of 1% by mole or more, based on the mole of the whole unit structure of the aromatic vinyl compound.

The aromatic vinyl compound may comprise optionally substituted vinylnaphthalene, acenaphthylene, or vinylcarbazole, and the polycyclic aromatic vinyl compound may be vinylnaphthalene, acenaphthylene, or vinylcarbazole.

The aromatic vinyl compound may comprise optionally substituted styrene and optionally substituted vinylnaphthalene, acenaphthylene, or vinylcarbazole, and the polycyclic aromatic vinyl compound may be vinylnaphthalene, acenaphthylene, or vinylcarbazole.

The aromatic vinyl compound may be optionally substituted styrene and optionally substituted vinylnaphthalene, acenaphthylene, or vinylcarbazole, and the polycyclic aromatic vinyl compound may be optionally substituted vinylnaphthalene, acenaphthylene, or vinylcarbazole.

The aromatic vinyl compound may consist of (a) polycyclic aromatic vinyl compound(s), and the aromatic vinyl compound may be optionally substituted vinylnaphthalene, acenaphthylene, or vinylcarbazole.

The polymer may have a unit structure of an aromatic vinyl compound in an amount of 60 to 95% by mole, based on the mole of the whole unit structure of the polymer.

The polymer may have a unit structure further having a crosslinking-forming group, wherein the crosslinking-forming group is a hydroxy group, an epoxy group, a protected hydroxy group, or a protected carboxyl group.

The neutralizing layer may be formed from a neutralizing layer-forming composition. The neutralizing layer-forming composition may contain the polymer having an aromatic compound-derived unit structure and/or the polymer having a polycyclic aromatic vinyl compound-derived unit structure, and examples of modes of these polymers are similar to those described in connection with the neutralizing layer. In the present specification, the term “underlayer film” frequently has the same meaning as the “neutralizing layer”, and the term “underlayer film-forming composition” frequently has the same meaning as the “neutralizing layer-forming composition”. The neutralizing layer-forming composition in the present invention may contain a crosslinking agent, an acid, or an acid generator.

<Crosslinking Agent>

The crosslinking agent used in the neutralizing layer-forming composition in the present invention includes melamine compounds, substituted urea compounds, and polymerized compounds thereof. Preferred is a crosslinking agent having at least two crosslinking forming substituents, and specific examples thereof include such compounds as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and methoxymethylated thiourea. Further, condensation products of any of the above compounds may be used.

Further, the crosslinking agent in the present invention may be the nitrogen-containing compound described in WO 2017/187969 A1, wherein the nitrogen-containing compound has 2 to 6 substituents represented by the following formula (1d) bonded to a nitrogen atom per molecule:

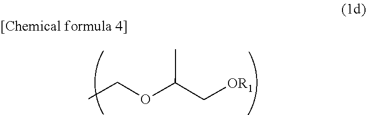

wherein R₁ represents a methyl group or an ethyl group.

The nitrogen-containing compound having per molecule 2 to 6 substituents represented by formula (1d) above may be a glycoluril derivative represented by the following formula (1E):

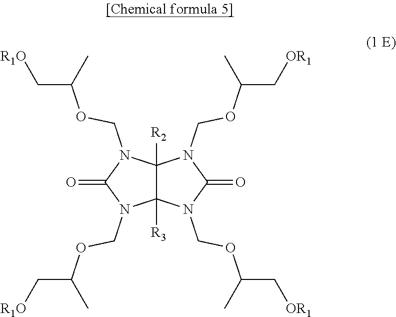

wherein each of four R₁'s independently represents a methyl group or an ethyl group, and each of R₂ and R₃ independently represents a hydrogen atom, an alkyl group having 1 to 4 carbon atoms, or a phenyl group.

Examples of the glycoluril derivatives represented by formula (1E) above include compounds represented by the following formulae (1E-1) to (1E-6).

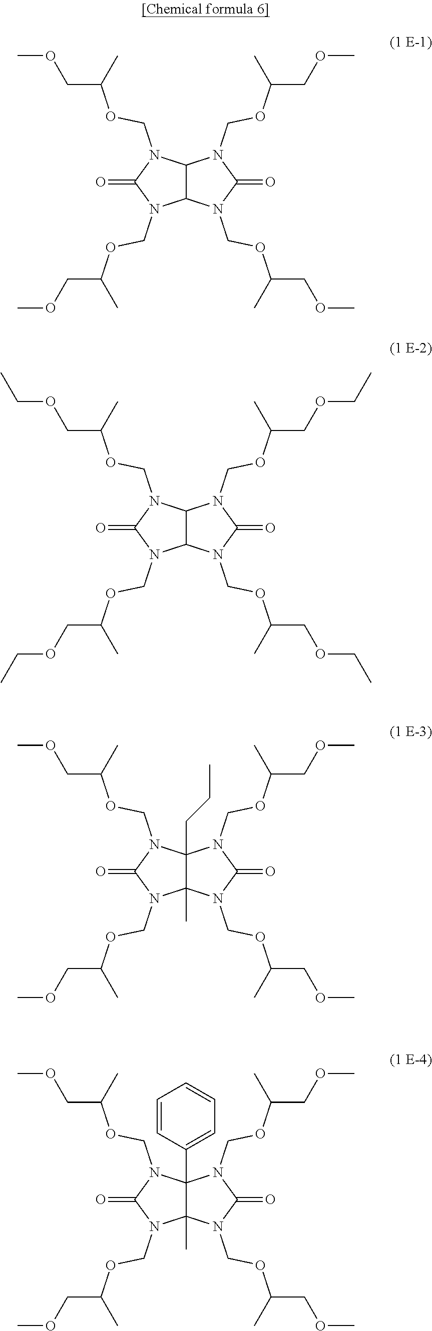

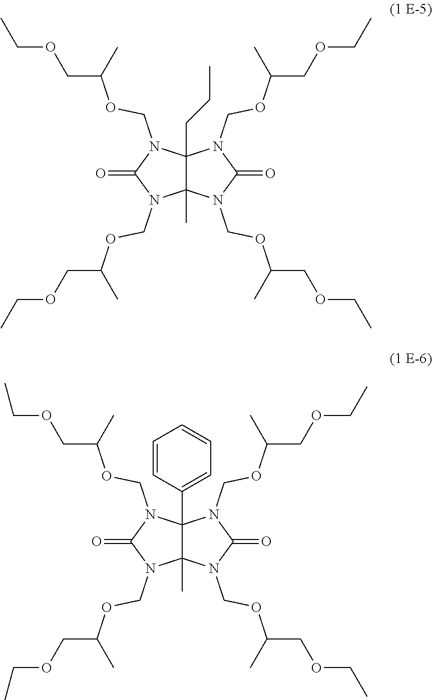

The nitrogen-containing compound having per molecule 2 to 6 substituents represented by formula (1d) above, such as the compound represented by formula (1E) above, is obtained by reacting a nitrogen-containing compound having per molecule 2 to 6 substituents represented by formula (2d) below bonded to a nitrogen atom with at least one compound represented by formula (3d) below:

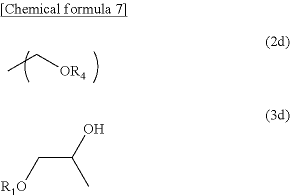

wherein R₁ represents a methyl group or an ethyl group, and R₄ represents an alkyl group having 1 to 4 carbon atoms.

The glycoluril derivative represented by formula (1E) above is obtained by reacting a glycoluril derivative represented by formula (2E) below with at least one compound represented by formula (3d) above.

The nitrogen-containing compound having per molecule 2 to 6 substituents represented by formula (2d) above is, for example, a glycoluril derivative represented by the following formula (2E):

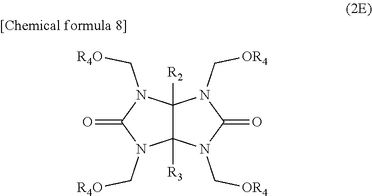

wherein each of R₂ and R₃ independently represents a hydrogen atom, an alkyl group having 1 to 4 carbon atoms, or a phenyl group; and each R₄ independently represents an alkyl group having 1 to 4 carbon atoms.

Examples of the glycoluril derivatives represented by formula (2E) above include compounds represented by formulae (2E-1) to (2E-4) below. Further, examples of the compounds represented by formula (3d) above include compounds represented by formulae (3d-1) and (3d-2) below.

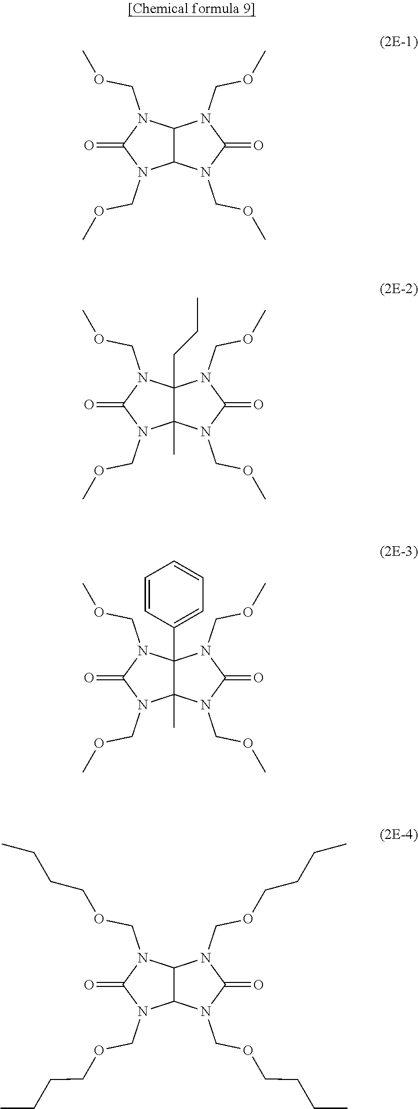

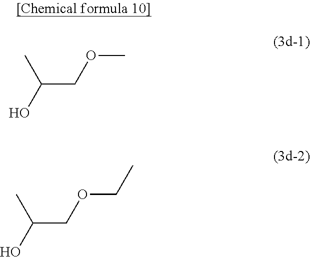

With regard to the nitrogen-containing compound having 2 to 6 substituents represented by formula (1d) bonded to a nitrogen atom per molecule, the disclosure of the corresponding parts in the specification of WO 2017/187969 A1 may apply.

The amount of the crosslinking agent added to the neutralizing layer-forming composition in the present invention is within the range of 0.001 to 80% by mass, preferably 0.01 to 50% by mass, further preferably 0.05 to 40% by mass, based on the mass of the solids in the neutralizing layer-forming composition. Although the crosslinking agent may possibly cause a crosslinking reaction due to self-condensation, it may cause a crosslinking reaction with a crosslinkable substituent, if the crosslinkable substituent is present in the above-mentioned polymer according to the present invention.

<Acid or Acid Generator>

The neutralizing layer-forming composition in the present invention may contain an acid or/and an acid generator as a catalyst for accelerating the crosslinking reaction. Examples of the acid include acidic compounds, such as p-toluenesulfonic acid, trifluoromethanesulfonic acid, pyridinium p-toluenesulfonate, salicylic acid, sulfosalicylic acid, citric acid, benzoic acid, hydroxybenzoic acid, and naphthalenecarboxylic acid. Examples of the acid generator include thermal acid generators, such as 2,4,4,6-tetrabromocyclohexadienone, benzoin tosylate, 2-nitrobenzyl tosylate, and other organic sulfonic acid alkyl esters. The acid or acid generator may be incorporated in an amount of 0.0001 to 20% by mass, preferably 0.0005 to 10% by mass, preferably 0.01 to 3% by mass, based on the mass of the solids in the neutralizing layer-forming composition of the present invention.

In addition to the thermal acid generators, examples of the acid generators include a photo-acid generator.

The photo-acid generator contained in the neutralizing layer-forming composition of the present invention includes onium salt compounds, sulfonimide compounds, and disulfonyldiazomethane compounds.

Examples of onium salt compounds include iodonium salt compounds, such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of sulfonimide compounds include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

A single species of photo-acid generator may be used, or two or more species of photo-acid generators may be used in combination.

When a photo-acid generator is used, it may be used in an amount of 0.01 to 5 parts by mass, or 0.1 to 3 parts by mass, or 0.5 to 1 part by mass, relative to 100 parts by mass of the solids in the neutralizing layer-forming composition of the present invention.

With respect to the details other than those described in the present specification as to the neutralizing layer-forming composition for forming the neutralizing layer, which contains the polymer having a polycyclic aromatic vinyl compound-derived unit structure, the disclosure of the corresponding parts concerning the underlayer film-forming composition for a self-assembled film described in the specification of WO 2014/097993 A1 may apply.

Further, the neutralizing layer may be an underlayer film formed from an underlayer film-forming composition for use in causing a layer comprising a block copolymer formed on a substrate to suffer phase separation, which is described in the specification of WO 2018/135455 A1, wherein the composition comprises a copolymer having:

(A) a unit structure derived from a styrene compound containing a tert-butyl group,

(B) a unit structure derived from an aromatic group-containing vinyl compound containing no hydroxy group, which differs from unit structure (A),

(C) a unit structure derived from a compound containing (a)an (meth)acryloyl group and containing no hydroxy group, and

(D) a unit structure derived from a crosslink-forming group-containing compound,

wherein the copolymer has a copolymerization ratio of: (A) 25 to 90% by mole, (B) 0 to 65% by mole, (C) 0 to 65% by mole, and (D) 10 to 20% by mole, and

wherein the copolymer has a proportion of an amount of unit structures containing an aromatic group based on a total amount of unit structures (A), (B), and (C) of 81 to 90% by mole.

Unit structure (A) derived from a styrene compound containing one or two tert-butyl groups may be represented by the following formula (1):

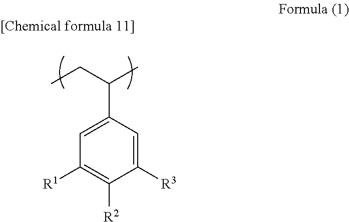

wherein one or two of R¹ to R³ are a tert-butyl group.

Unit structure (D) derived from a crosslinking-forming group-containing compound may be represented by the following formula (2-1), (2-2), (3-1), or (3-2):

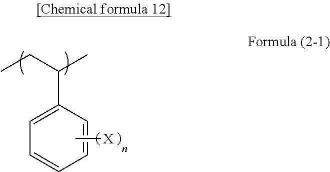

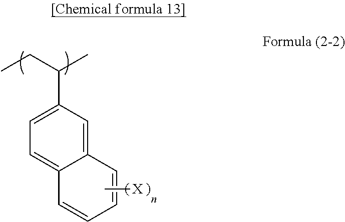

wherein, in formulae (2-1) and (2-2), each of n quantity of X independently represents a hydroxy group, a halogen atom, an alkyl group, an alkoxy group, a cyano group, an amide group, an alkoxycarbonyl group, or a thioalkyl group, and n represents an integer of 1 to 7,

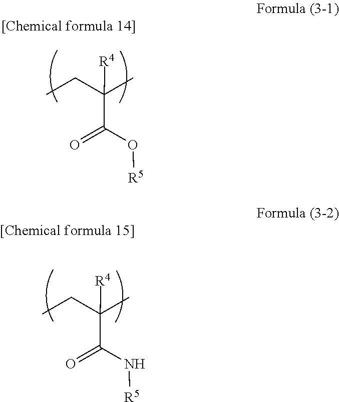

wherein, in formulae (3-1) and (3-2),
R⁴ represents a hydrogen atom or a methyl group, and
R⁵ represents a linear, branched, or cyclic alkyl group having 1 to 10 carbon atoms and having a hydroxy group and optionally being substituted with a halogen atom, or a hydroxyphenyl group.

Unit structure (B), which is a unit structure derived from an aromatic group-containing vinyl compound containing no hydroxy group, and which is other than Unit structure (A), may be represented by the following formula (4-1) or (4-2):

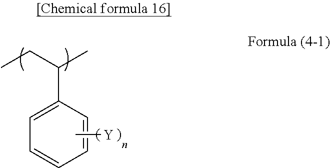

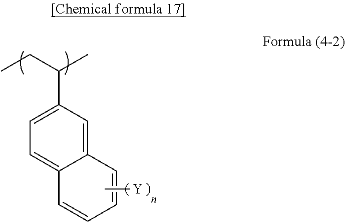

wherein each of n quantity of Y independently represents a halogen atom, an alkyl group, an alkoxy group, a cyano group, an amide group, an alkoxycarbonyl group, or a thioalkyl group, and n represents an integer of 0 to 7.

Unit structure (C) derived from a compound containing (a)an (meth)acryloyl group and containing no hydroxy group may be represented by the following formula (5-1) or (5-2):

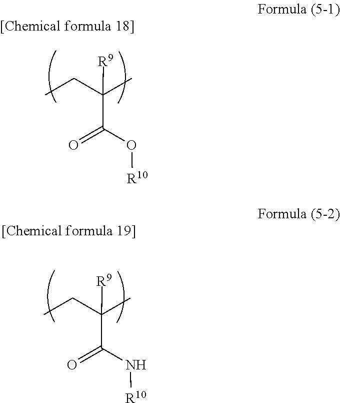

wherein R⁹ represents a hydrogen atom or a methyl group, and each R¹⁰ independently represents a hydrogen atom, an alkoxy group having 1 to 5 carbon atoms, a linear, branched, or cyclic alkyl group having 1 to 10 carbon atoms and optionally being substituted with a halogen atom, a benzyl group, or an anthrylmethyl group.

Unit structure (B), which is a unit structure derived from an aromatic group-containing vinyl compound containing no hydroxy group, and which is other than Unit structure (A), may be a unit structure derived from vinylnaphthalene.

Further, with respect to the details other than those described in the present specification as to the underlayer film-forming composition in the present invention, the disclosure of WO 2018/135455 A1 may apply.

Further, the neutralizing layer may be formed from the primer described in the specification of JP 2012-062365 A, wherein the primer is for use in causing a layer comprising a block copolymer having more than one species of polymers bonded to each other formed on a substrate to suffer phase separation, wherein the primer contains a resin component, wherein 20 to 80% by mole of the constituent units of the whole resin component is an aromatic ring-containing monomer-derived constituent unit.

The resin component may contain a non-aromatic ring-containing monomer-derived constituent unit.

The non-aromatic ring-containing monomer may be a vinyl compound or (meth)acrylic acid compound containing at least one atom selected from the group consisting of N, O, Si, P, and S.

The aromatic ring-containing monomer may be selected from the group consisting of an aromatic compound having 6 to 18 carbon atoms and having a vinyl group, an aromatic compound having 6 to 18 carbon atoms and having (a)an (meth)acryloyl group, and a phenol which is a constituent of a novolak resin. Further, the aromatic ring-containing monomer may have a polymerizable monomer, or the resin component may contain a polymerizable group.

The term “(meth)acrylic acid” means one or both of an acrylic acid having a hydrogen atom bonded at the α-position and methacrylic acid having a methyl group bonded at the α-position. The terms “(meth)acrylic acid ester”, “(meth)acrylate”, and “(meth)acryloyl” are similarly interpreted.

Examples of aromatic compounds having 6 to 18 carbon atoms and having a vinyl group include monomers having a group corresponding to, for example, a phenyl group, a biphenyl group, a fluorenyl group, a naphthyl group, an anthryl group, or a phenanthryl group, in which a hydrogen atom of the aromatic ring is replaced by a vinyl group, and monomers having a heteroaryl group corresponding to the above group in which part of carbon atoms constituting the ring is replaced by a heteroatom, such as an oxygen atom, a sulfur atom, or a nitrogen atom. These monomers may have a substituent in addition to a vinyl group.

Examples of such monomers include α-methylstyrene, 2-methylstyrene, 3-methyl styrene, 4-methyl styrene, 4-t-butyl styrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, vinylcyclohexane, 4-vinylbenzyl chloride, 1-vinylnaphthalene, 4-vinylbiphenyl, 1-vinyl-2-pyrrolidone, 9-vinylanthracene, and vinylpyridine.

Examples of aromatic compounds having 6 to 18 carbon atoms and having (a)an (meth)acryloyl group include monomers having a group corresponding to, for example, a phenyl group, a biphenyl group, a fluorenyl group, a naphthyl group, an anthryl group, or a phenanthryl group, in which a hydrogen atom of the aromatic ring is replaced by (a)an (meth)acryloyl group, and monomers having a heteroaryl group corresponding to the above group in which part of the carbon atoms constituting the ring is replaced by a heteroatom, such as an oxygen atom, a sulfur atom, or a nitrogen atom. These monomers may have a substituent in addition to (a)an (meth)acryloyl group.

Examples of such monomers include benzyl methacrylate, 1-naphthalene (meth)acrylate, 4-methoxynaphthalene (meth)acrylate, 9-anthracene (meth)acrylate, and phenoxyethyl (meth)acrylate. With respect to the details other than those described in the present specification as to the primer, the disclosure of the corresponding parts in the specification of JP 2012-062365 A may apply.

The weight average molecular weight of the polymer contained in the neutralizing layer in the present invention is, for example, within the range of 1,000 to 50,000, or 2,000 to 30,000.

The neutralizing layer-forming composition in the present invention preferably contains the polymer used in the neutralizing layer, and a solvent. Specific examples of preferred solvents are the same ones as in the above-mentioned block copolymer layer-forming composition (preferably PS-b-PMMA layer-forming composition).

In an embodiment of the present invention, the neutralizing layer may comprise a polymer having a unit structure containing an aliphatic polycyclic structure of an aliphatic polycyclic compound in the principal chain.

The polymer may be a polymer having a unit structure containing in the principal chain an aliphatic polycyclic structure of an aliphatic polycyclic compound and an aromatic ring structure of an aromatic ring-containing compound.

The polymer may be a polymer having a unit structure containing in the principal chain an aliphatic polycyclic structure of an aliphatic polycyclic compound and a polymeric chain derived from a vinyl group of a vinyl group-containing compound.

The polymer may have a unit structure represented by the following formula (1a):

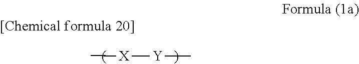

wherein X is a single bond, a divalent group having a vinyl structure derived from a vinyl group-containing compound as a polymeric chain, or a divalent group having an aromatic ring-containing structure derived from an aromatic ring-containing compound as a polymeric chain; and Y is a divalent group having an aliphatic polycyclic structure derived from an aliphatic polycyclic compound as a polymeric chain.

The aliphatic polycyclic compound may be a di-, tri-, tetra-, penta-, or hexa-cyclic diene compound.

The aliphatic polycyclic compound may be dicyclopentadiene or norbornadiene.

The vinyl group-containing compound may be an alkene, an acrylate, or a methacrylate. The aromatic ring-containing compound may be a monocyclic compound or a heterocyclic compound.

The monocyclic compound may be optionally substituted benzene or optionally substituted naphthalene.

The heterocyclic compound may be optionally substituted carbazole or optionally substituted phenothiazine.

The polymer represented by formula (1a) above has, for example, unit structures represented by the following formulae (3-1a) to (3-12a).

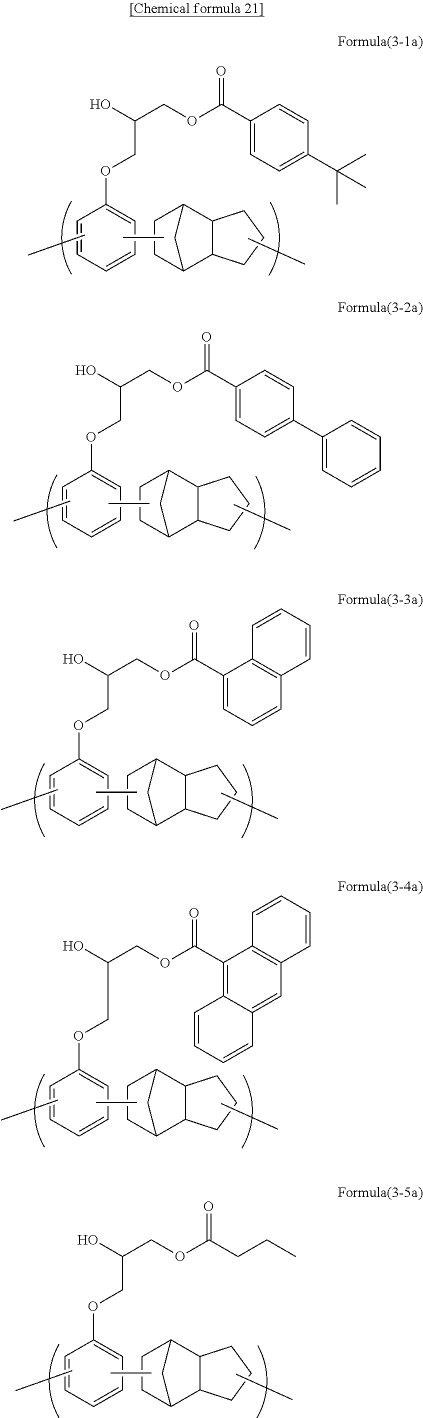

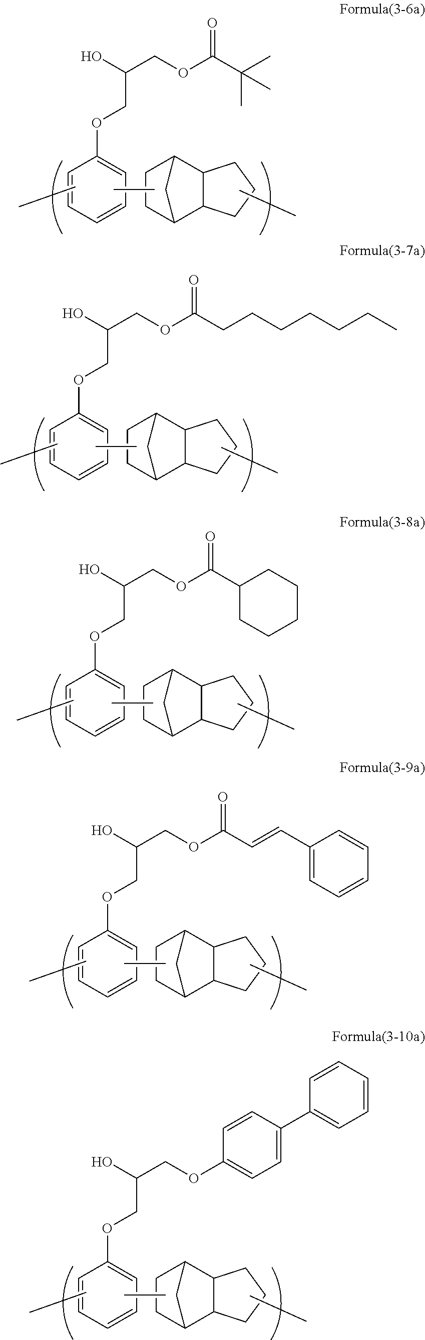

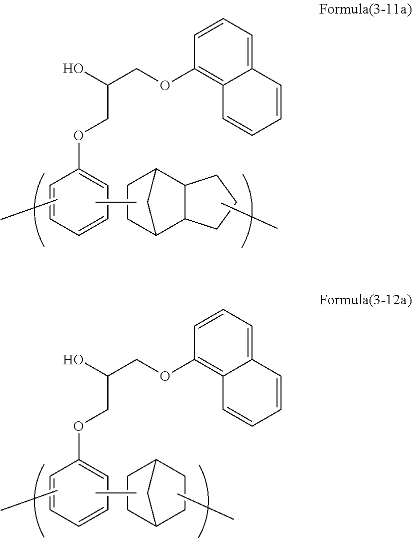

With regard to the details of the neutralizing layer comprising a polymer having a unit structure containing an aliphatic polycyclic structure of an aliphatic polycyclic compound in the principal chain, the disclosure of the corresponding parts of WO 2015/041208 A apply.

The neutralizing layer in the present invention may comprise a polysiloxane.

The polysiloxane may be a hydrolytic condensation product of silane containing a phenyl group-containing silane.

The polysiloxane may be a hydrolytic condensation product of silane containing a silane represented by the following formula (1b):

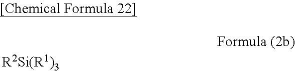

wherein R¹ represents an alkoxy group, an acyloxy group, or a halogen atom; and R² represents an organic group which contains a benzene ring optionally having a substituent, and which is bonded to the silicon atom through a Si—C bond, in an amount of 10 to 100% by mole, based on the total mole of the silanes, and preferably in an amount of 80 to 100% by mole.

The polysiloxane may be a hydrolytic condensation product of silane containing the silane represented by formula (1b) above, a silane represented by formula (2b) below, and a silane represented by formula (3b) below in such amounts that the ratio of the silane represented by formula (1b):silane represented by formula (2b):silane represented by formula (3b) is 10 to 100:0 to 90:0 to 50, in terms of % by mole, based on the total mole of the silanes:

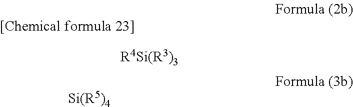

wherein R³ and R⁵ represent an alkoxy group, an acyloxy group, or a halogen atom, and R⁴ represents an organic group which contains a hydrocarbon optionally having a substituent, and which is bonded to the silicon atom through a Si—C bond.

The polysiloxane may be a hydrolytic condensation product of silane containing the silane represented by formula (1b) above and the silane represented by formula (2b) above in a ratio of 10 to 100:0 to 90, in terms of % by mole, based on the total mole of the silanes.

The polysiloxane may be a hydrolytic condensation product of silane containing the silane represented by formula (1b) above and the silane represented by formula (3b) above in a ratio of 10 to 100:0 to 90, in terms of % by mole, based on the total mole of the silanes.

In formula (1b) above, R² may be a phenyl group. In formula (2b) above, R⁴ may be a methyl group or a vinyl group. In formula (3b) above, R⁵ may be an ethyl group.

With regard to the details of the neutralizing layer comprising a polysiloxane, the disclosure of the corresponding parts in the specification of WO 2013/146600 A1 may apply.

The vertically phase-separated layer of a block copolymer, preferably PS-b-PMMA layer, may be formed using a brush material as the neutralizing layer.

For example, as in the method using a polymer brush described in JP 2016-160431 A, a block copolymer lower layer (neutralizing layer) may be formed by a method which comprises applying a composition onto a substrate, wherein the composition comprises: a block copolymer comprising a first polymer and a second polymer, wherein the first polymer and the second polymer of the block copolymer are different from each other, and the block copolymer forms a phase-separated structure; an addition polymer comprising a bottlebrush polymer, wherein the bottlebrush polymer comprises a polymer having a surface energy lower than or higher than that of the block copolymer; and a solvent.

Alternatively, the method using a brush material described in Science 7 Mar. 1997: Vol. 275, Issue 5305, pp. 1458-1460 may be used.

A preferred brush material in the present invention comprises a polymer having a reactive substituent at the terminal thereof. That is, in an embodiment of the present invention, the neutralizing layer comprises a polymer having a reactive substituent at the terminal thereof.

The reactive substituent means a substituent capable of bonding to, for example, silicon, SiN, SiON, or a silicon hard mask, and contributes to block copolymer orientation as the so-called brush material. Examples of the reactive substituents include a hydroxy group, a 1,2-ethanediol group, a carboxyl group, an amino group, a thiol group, a phosphoric acid group, and a methine group.

Specific examples of polymers having a reactive substituent at the terminal thereof include a polystyrene/poly(methyl methacrylate) random copolymer having a hydroxy group at the terminal thereof. The molar ratio of polystyrene to the whole random copolymer is preferably 60% by mole or more, 65% by mole or more, 70% by mole or more, 80% by mole or more, 81% by mole or more, 85% by mole or more, or 90% by mole or more. The polymer forming the brush material has a weight average molecular weight, for example, in the range of from 5,000 to 50,000. The polymer preferably has a polydisperse degree (Mw/Mn) of 1.30 to 2.00.

The silicon hard mask may be a known silicon hard mask (referred to also as “silicon-containing resist underlying film”), and includes the silicon hard mask (silicon-containing resist underlying film) described in, for example, WO2019/181873, WO2019/124514, WO2019/082934, WO2019/009413, WO2018/181989, WO2018/079599, WO2017/145809, WO2017/145808, and WO2016/031563.

<Substrate>

The vertically phase-separated layer of a block copolymer, preferably PS-b-PMMA layer, is preferably formed on a substrate.

The substrate may be the so-called semiconductor substrate, and examples include a silicon wafer, a germanium wafer, and compound semiconductor wafers, such as gallium arsenide, indium phosphide, gallium nitride, indium nitride, and aluminum nitride.

When a semiconductor substrate having an inorganic film formed on the surface thereof is used, the inorganic film is formed by, for example, an ALD (atomic layer deposition) method, a CVD (chemical vapor deposition) method, a reactive sputtering method, an ion plating method, a vacuum deposition method, or a spin coating method (spin on glass: SOG). Examples of the inorganic films include a polysilicon film, a silicon oxide film, a silicon nitride film, a BPSG (Boro-Phospho Silicate Glass) film, a titanium nitride film, a titanium nitride oxide film, a tungsten film, a gallium nitride film, and a gallium arsenide film.

The neutralizing layer-forming composition is applied onto the semiconductor substrate by an appropriate application method, for example, using a spinner or a coater. Then, the composition applied is baked using a heating means, such as a hotplate, to form a neutralizing layer. Baking conditions are appropriately selected from those at a baking temperature of 100 to 400° C. for a baking time of 0.3 to 60 minutes. Preferred are conditions at a baking temperature of 120 to 350° C. for a baking time of 0.5 to 30 minutes, and more preferred are conditions at a baking temperature of 150 to 300° C. for a baking time of 0.8 to 10 minutes.

The thickness of the formed neutralizing layer is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), or 0.005 μm (5 nm) to 0.02 μm (20 nm).

Phase separation of the layer of the block copolymer may be conducted in the presence of the upper layer film by a treatment for inducing reorientation of the block copolymer material, for example, a treatment with ultrasonic waves, a treatment with a solvent, or heat annealing. In many uses, it is desired that phase separation of the layer of the block copolymer is achieved by merely heating or by the so-called heat annealing. The heat annealing can be conducted in air or in an inert gas under atmospheric pressure or a reduced pressure or under pressuring conditions.

<Method for Producing a Vertically Phase-Separated Layer of a Block Copolymer>

The method for producing a vertically phase-separated layer of a block copolymer, preferably PS-b-PMMA layer, of the present invention comprises the steps of: forming a block copolymer layer, preferably a PS-b-PMMA layer, on a substrate; and then heating the substrate under a pressure lower than atmospheric pressure. The detailed conditions for the method and others are the same as those described above in connection with the vertically phase-separated layer of a block copolymer, preferably PS-b-PMMA layer.

Phase separation of the layer of the block copolymer, preferably PS-b-PMMA layer, forms block copolymer domains oriented substantially vertically with respect to the surface of the substrate or neutralizing layer. The form of the domains is, for example, a lamellar form, a spherical form, or a cylinder (cylindrical) form. A gap between the domains is, for example, 50 nm or less, 40 nm or less, 30 nm or less, 20 nm or less, or 10 nm or less. By the method of the present invention, a vertically phase-separated layer of a block copolymer, preferably PS-b-PMMA layer, having a desired size, form, orientation, and periodic properties may be formed.

<Method for Producing a Semiconductor Device>

The vertically phase-separated layer of a block copolymer, preferably PS-b-PMMA layer, by the above-mentioned method may be further subjected to the step of etching the layer. Generally, before etching, part of the phase-separated block copolymer layer, preferably PS-b-PMMA layer, is removed. The etching may be conducted by a known means. This method may be used for producing a semiconductor substrate.

Specifically, the method for producing a semiconductor device of the present invention comprises the steps of: (1) forming a neutralizing layer on a substrate using the neutralizing layer-forming composition in the present invention; (2) forming a block copolymer layer, preferably a PS-b-PMMA layer, on the neutralizing layer; (3) causing the layer of the block copolymer, preferably PS-b-PMMA layer, formed on the neutralizing layer to suffer phase separation; (4) subjecting the phase-separated block copolymer layer, preferably PS-b-PMMA layer, to etching; and (5) subjecting the substrate to etching.

In etching, for example, there may be used a gas, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane.

By using the pattern of the vertically phase-separated layer of a block copolymer, preferably PS-b-PMMA layer, of the present invention, it is possible to impart a desired form to a substrate to be processed by etching, producing an advantageous semiconductor device.

### EXAMPLES

Hereinbelow, the present invention will be described in more detail with reference to the following Examples and Comparative Examples, which should not be construed as limiting the scope of the present invention.

### Example 1

(Preparation of Block Copolymer 1)

0.5 g of a polystyrene/poly(methyl methacrylate) copolymer (manufactured by POLYMER SOURCE INC.; PS (Mw: 39,800; Mn: 37,500)-b-PMMA (Mw: 19,100; Mn: 18,000); polydisperse degree: 1.06), which is a block copolymer, was dissolved in 24.5 g of propylene glycol monomethyl ether acetate, to obtain a 2% by mass solution. Thereafter, the obtained solution was subjected to filtration using a polyethylene microfilter having a pore diameter of 0.02 μm, to prepare a solution of block copolymer 1 for self-assembled film-forming composition 1.

The weight average molecular weight (Mw) values of the polymers shown in the Synthesis Examples below are the results of measurement made by a gel permeation chromatography (GPC) method. In the measurement, a GPC apparatus, manufactured by Tosoh Corp., was used, and the conditions for the measurement are as follows.

Measuring apparatus: HLC-8020GPC [trade name] (manufactured by Tosoh Corp.)
GPC Columns: TSKgel G2000HXL [trade name]: two columns; G3000HXL [trade name]: one column; G4000HXL [trade name]: one column (each of which is manufactured by Tosoh Corp.)
Column temperature: 40° C.

### Solvent: Tetrahydrofuran (THF)

Flow rate: 1.0 ml/minute
Standard sample: Polystyrene (manufactured by Tosoh Corp.)

(Preparation of Block Copolymer 2)

A solution of block copolymer 2 was prepared in the same manner as in the preparation of block copolymer 1, except that a polystyrene/poly(methyl methacrylate) copolymer (manufactured by POLYMER SOURCE INC.; PS (Mw: 50,200; Mn: 46,100)-b-PMMA (Mw: 22,900; Mn: 21,000); polydisperse degree: 1.09) was used instead of the polystyrene/poly(methyl methacrylate) copolymer (manufactured by POLYMER SOURCE INC.; PS (Mw: 39,800; Mn: 37,500)-b-PMMA (Mw: 19,100; Mn: 18,000); polydisperse degree: 1.06).

(Preparation of Block Copolymer 3)

A solution of block copolymer 3 was prepared in the same manner as in the preparation of block copolymer 1, except that a polystyrene/poly(methyl methacrylate) copolymer (manufactured by POLYMER SOURCE INC.; PS (Mw: 59,900; Mn: 55,000)-b-PMMA (Mw: 23,900; Mn: 22,000); polydisperse degree: 1.09) was used instead of the polystyrene/poly(methyl methacrylate) copolymer (manufactured by POLYMER SOURCE INC.; PS (Mw: 39,800; Mn: 37,500)-b-PMMA (Mw: 19,100; Mn: 18,000); polydisperse degree: 1.06).

(Preparation of Block Copolymer 4)

A solution of block copolymer 4 was prepared in the same manner as in the preparation of block copolymer 1, except that a polystyrene/poly(methyl methacrylate) copolymer (manufactured by POLYMER SOURCE INC.; PS (Mw: 28,700; Mn: 26,800)-b-PMMA (Mw: 13,100; Mn: 12,200); polydisperse degree: 1.09) was used instead of the polystyrene/poly(methyl methacrylate) copolymer (manufactured by POLYMER SOURCE INC.; PS (Mw: 39,800; Mn: 37,500)-b-PMMA (Mw: 19,100; Mn: 18,000); polydisperse degree: 1.06).

### [Synthesis Example 1] Synthesis of Polymer 1

6.23 g (molar ratio to the whole polymer 1:85%) of 2-vinylnaphthalene, 0.93 g (molar ratio to the whole polymer 1:15%) of hydroxyethyl methacrylate, and 0.36 g of 2,2′-azobisisobutyronitrile were dissolved in 22.50 g of propylene glycol monomethyl ether acetate. Thereafter, the resultant solution was heated and stirred at 85° C. for about 24 hours. The resultant reaction mixture was added dropwise to methanol, and the deposited material was collected by suction filtration, which was then subjected to vacuum drying at 60° C. to recover polymer 1. The polymer had a weight average molecular weight Mw of 6,000, as determined by GPC using a molecular weight conversion calibration curve obtained from the polystyrene.

### [Synthesis Example 2] Synthesis of Polymer 2

4.77 g (molar ratio to the whole polymer 2:60%) of 2-vinylnaphthalene, 1.34 g (molar ratio to the whole polymer 2:20%) of hydroxyethyl methacrylate, 1.03 g (molar ratio to the whole polymer 2:20%) of methyl methacrylate, and 0.36 g of 2,2′-azobisisobutyronitrile were dissolved in 22.50 g of propylene glycol monomethyl ether acetate. Thereafter, the resultant solution was heated and stirred at 85° C. for about 24 hours. The resultant reaction mixture was added dropwise to methanol, and the deposited material was collected by suction filtration, which was then subjected to vacuum drying at 60° C. to recover polymer 2. The polymer had a weight average molecular weight Mw of 6,000, as determined by GPC using a molecular weight conversion calibration curve obtained from the polystyrene.

### [Synthesis Example 3] Synthesis of Polymer 3

2.57 g (molar ratio to the whole polymer 3:50%) of 2-vinylnaphthalene, 2.06 g (molar ratio to the whole polymer 3:35%) of benzyl methacrylate, 0.72 g (molar ratio to the whole polymer 3:15%) of hydroxyethyl methacrylate, and 0.33 g of 2,2′-azobisisobutyronitrile were dissolved in 22.50 g of propylene glycol monomethyl ether acetate. Thereafter, the resultant solution was heated and stirred at 85° C. for about 24 hours. The resultant reaction mixture was added dropwise to methanol, and the deposited material was collected by suction filtration, which was then subjected to vacuum drying at 60° C. to recover polymer 3. The polymer had a weight average molecular weight Mw of 5,900, as determined by GPC using a molecular weight conversion calibration curve obtained from the polystyrene.

### [Synthesis Example 4] Synthesis of Polymer 4

6.13 g (molar ratio to the whole polymer 4:85%) of 2-vinylnaphthalene, 1.01 g (molar ratio to the whole polymer 4:15%) of hydroxypropyl methacrylate, and 0.36 g of 2,2′-azobisisobutyronitrile were dissolved in 22.50 g of propylene glycol monomethyl ether acetate. Thereafter, the resultant solution was heated and stirred at 85° C. for about 24 hours. The resultant reaction mixture was added dropwise to methanol, and the deposited material was collected by suction filtration, which was then subjected to vacuum drying at 60° C. to recover polymer 4. The polymer had a weight average molecular weight Mw of 6,200, as determined by GPC using a molecular weight conversion calibration curve obtained from the polystyrene.

### [Synthesis Example 5] Synthesis of Polymer 5

11.00 g (molar ratio to the whole polymer 5:80%) of vinylcarbazole, 1.85 g (molar ratio to the whole polymer 5:20%) of hydroxyethyl methacrylate, and 0.39 g of 2,2′-azobisisobutyronitrile were dissolved in 30.89 g of propylene glycol monomethyl ether acetate. Thereafter, the resultant solution was heated and stirred at 85° C. for about 19 hours. The obtained polymer 5 had a weight average molecular weight Mw of 6,950, as determined by GPC using a molecular weight conversion calibration curve obtained from the polystyrene.

### [Synthesis Example 6] Synthesis of Polymer 6

34.98 g of propylene glycol monomethyl ether was added to 5.00 g of a dicyclopentadiene epoxy resin (trade name: EPICLON HP-7200H, manufactured by DIC Corporation), 3.58 g of 4-phenylbenzoic acid, and 0.17 g of ethyltriphenylphosphonium bromide, and the resultant mixture was heated under reflux in a nitrogen gas atmosphere for 16 hours. The obtained polymer 6 had a weight average molecular weight Mw of 1,800, as determined by GPC using a molecular weight conversion calibration curve obtained from the polystyrene.

### [Synthesis Example 7] Synthesis of Polymer 7

36.89 g of propylene glycol monomethyl ether was added to 5.50 g of a dicyclopentadiene epoxy resin (trade name: EPICLON HP-7200H, manufactured by DIC Corporation), 3.54 g of 4-tert-butylbenzoic acid, and 0.18 g of ethyltriphenylphosphonium bromide, and the resultant mixture was heated under reflux in a nitrogen gas atmosphere for 15 hours. The obtained polymer 7 had a weight average molecular weight Mw of 2,000, as determined by GPC using a molecular weight conversion calibration curve obtained from the polystyrene.

### [Synthesis Example 8] Synthesis of Polymer 8

16.85 g of phenyltrimethoxysilane (contained in an mount of 85% by mole, based on the total mole of the silanes), 3.13 g of tetraethoxysilane (contained in an amount of 15% by mole, based on the total mole of the silanes), and 28.84 g of acetone were placed in a 100 ml flask. While stirring the resultant mixture solution by a magnetic stirrer, 5.47 g of 0.01 mol/1 hydrochloric acid was dropwise added to the mixture solution. After the addition, the flask was placed in an oil bath adjusted to 85° C., and a reaction was conducted by heating under reflux for 4 hours. Then, the resultant reaction solution was cooled to room temperature, and 72 g of propylene glycol monomethyl ether acetate was added to the reaction solution. Then, methanol, ethanol, water, and hydrochloric acid, which are by-products of the reaction, were distilled off under a reduced pressure, followed by concentration, obtaining a polymer solution. Propylene glycol monoethyl ether was added to the polymer solution so as to adjust the solvent ratio, i.e., the propylene glycol monomethyl ether acetate/propylene glycol monoethyl ether ratio, to 20/80. The obtained polymer 8 had a weight average molecular weight Mw of 1,200, as determined by GPC using a molecular weight conversion calibration curve obtained from the polystyrene.

(Preparation of Underlayer Film-Forming Composition 1)

0.39 g of the polymer obtained in Synthesis Example 1 was mixed with 0.10 g of tetramethoxymethylglycoluril and 0.05 g of pyridinium p-toluenesulfonate. The resultant mixture was dissolved by adding thereto 69.65 g of propylene glycol monomethyl ether acetate and 29.37 g of propylene glycol monomethyl ether. Then, the resultant solution was subjected to filtration using a polyethylene microfilter having a pore diameter of 0.02 μm to prepare a solution, which is an underlayer film-forming composition for a self-assembled film.

(Preparation of Underlayer Film-Forming Compositions 2 to 5)

Underlayer film-forming compositions 2 to 5 were prepared in the same manner as in the preparation of underlayer film-forming composition 1, except that each of the polymers obtained in Synthesis Examples 2 to 5 was used instead of the polymer obtained in Synthesis Example 1.

(Preparation of Underlayer Film-Forming Composition 6)

0.26 g of the polymer obtained in Synthesis Example 6 was mixed with 0.07 g of tetramethoxymethylglycoluril and 0.007 g of pyridinium p-toluenesulfonate. The resultant mixture was dissolved by adding thereto 8.90 g of propylene glycol monomethyl ether acetate and 20.76 g of propylene glycol monomethyl ether. Then, the resultant solution was subjected to filtration using a polyethylene microfilter having a pore diameter of 0.02 μm to prepare a solution, which is underlayer film-forming composition 6 for a self-assembled film.

(Preparation of Underlayer Film-Forming Composition 7)

Underlayer film-forming composition 7 was prepared in the same manner as in the preparation of underlayer film-forming composition 6, except that the polymer obtained in Synthesis Example 7 was used instead of the polymer obtained in Synthesis Example 6.

(Preparation of Underlayer Film-Forming Composition 8)

1.33 g of the polymer obtained in Synthesis Example 8 was mixed with 0.006 g of maleic acid and 0.0012 g of benzyltriethylammonium chloride. The resultant mixture was dissolved by adding thereto 0.68 g of propylene glycol monomethyl ether acetate, 0.79 g of propylene glycol monomethyl ether, 9.10 g of 1-ethoxy-2-propanol, and 1.30 g of ultrapure water. Then, the resultant solution was subjected to filtration using a fluororesin microfilter having a pore diameter of 0.1 μm to prepare a solution, which is underlayer film-forming composition 8 for a self-assembled film.

(Preparation of Underlayer Film-Forming Composition 9 Using a Brush Material)

0.3 g of a polystyrene/poly(methyl methacrylate) random copolymer having a hydroxy group at the terminal thereof (manufactured by POLYMER SOURCE INC.; polystyrene molar ratio: 80%; poly(methyl methacrylate) molar ratio: 20%; Mw: 14,500; polydisperse degree: 1.40) was dissolved in 29.7 g of propylene glycol monomethyl ether acetate to obtain a 1% by mass solution. Then, the obtained solution was subjected to filtration using a polyethylene microfilter having a pore diameter of 0.02 μm to prepare a solution, which is underlayer film-forming composition 9 using a brush material.

### Example 2

(Evaluation of Self-Assembly of the Block Copolymer)

The above-obtained underlayer film-forming composition 1 for a self-assembled film was applied onto a silicon wafer, and heated on a hotplate at 240° C. for one minute to obtain an underlayer film (A layer) having a thickness of 5 to 10 nm. The self-assembled film-forming composition containing block copolymer 1 was applied onto the underlayer film by a spin coater, and heated on a hotplate at 100° C. for one minute to form a self-assembled film (B layer) having a thickness of 40 nm. The wafer with the self-assembled film applied thereonto was heated using an etching machine (Lam 2300 MWS), manufactured by Lam Research Corporation, in an O₂/N₂ mixed gas atmosphere (mixing ratio is O₂:N₂=2:8 (flow rate ratio)) at 290° C. under a pressure of 760 mTorr for 15 minutes, inducing a micro-phase-separated structure in the self-assembled film.

(Observation of Micro-Phase-Separated Structure)

The silicon wafer with the micro-phase-separated structure induced was subjected to etching for 3 seconds using an etching machine (Lam 2300 Versys Kiyo45) manufactured by Lam Research Corporation, and using O₂/N₂ gas as an etching gas, so that the poly(methyl methacrylate) region was preferentially etched. Subsequently, the resultant structure was observed in respect of the shape by means of an electron microscope (S-4800, manufactured by Hitachi High-Technologies Corporation).

### Examples 3 to 5

Observation of micro-phase-separated structure was conducted in the same manner as in Example 2, except that underlayer film-forming compositions 2 to 4 were used instead of underlayer film-forming composition 1.

### Examples 6 and 7

Observation of micro-phase-separated structure was conducted in the same manner as in Example 2, except that the heating was conducted in either N₂ or O₂ gas instead of in an O₂/N₂ mixed gas atmosphere.

### Examples 8 and 9

Observation of micro-phase-separated structure was conducted in the same manner as in Example 6, except that the heating was conducted at 270° C. or 300° C. instead of at 290° C.

### Examples 10 and 11

Observation of micro-phase-separated structure was conducted in the same manner as in Example 6, except that the heating was conducted under a pressure of either 50 mTorr or 10,000 mTorr instead of under a pressure of 760 mTorr.

### Examples 12 and 13

Observation of micro-phase-separated structure was conducted in the same manner as in Example 6, except that the heating was conducted at 300° C. for either 3 minutes or 5 minutes instead of at 290° C. for 15 minutes.

### Example 14

Observation of micro-phase-separated structure was conducted in the same manner as in Example 2, except that the heating was conducted using a vacuum heating apparatus (VJ-300-S), manufactured by Ayumi Industry Co., Ltd. in a nitrogen gas atmosphere at 290° C. under 760 mTorr for 15 minutes instead of using an etching machine (Lam 2300 MWS), manufactured by Lam Research Corporation, in an O₂/N₂ mixed gas atmosphere (mixing ratio is O₂:N₂=2:8 (flow rate ratio)) at 290° C. under a pressure lower than atmospheric pressure for 15 minutes.

### Examples 15 to 21

Observation of micro-phase-separated structure was conducted in the same manner as in Example 14, except that each of underlayer film-forming compositions 2 to 8 was used instead of underlayer film-forming composition 1.

### Examples 22 to 25

Observation of micro-phase-separated structure was conducted in the same manner as in Example 14, except that the heating was conducted at either 240° C., 260° C., 270° C., or 300° C. instead of at 290° C.

### Example 26

Observation of micro-phase-separated structure was conducted in the same manner as in Example 14, except that the heating was conducted at 320° C. for 5 minutes instead of at 290° C. for 15 minutes.

### Examples 27 and 28

Observation of micro-phase-separated structure was conducted in the same manner as in Example 14, except that the heating was conducted under a pressure of either 250 mTorr or 5,000 mTorr instead of under a pressure of 760 mTorr.

### Examples 29 to 31

Observation of micro-phase-separated structure was conducted in the same manner as in Example 14, except that each of the solutions of block copolymers 2 to 4 was used instead of the solution of block copolymer 1.

### Example 32

Observation of micro-phase-separated structure was conducted in the same manner as in Example 14, by replacing the underlayer film prepared by applying underlayer film-forming composition 1 onto a silicon wafer and heating the composition on a hotplate at 240° C. for one minute with an underlayer film, which was prepared by the steps of: applying underlayer film-forming composition 9 onto a silicon wafer, heating the composition on a hotplate at 200° C. for 2 minutes, and immersing the silicon wafer in propylene glycol monomethyl ether acetate to remove the polymer not deposited on the silicon wafer.

### Comparative Example 1

Observation of micro-phase-separated structure was conducted in the same manner as in Example 2, except for conducting the heating on a hotplate in an air atmosphere at 290° C. under atmospheric pressure (760,000 mTorr) for 15 minutes instead of conducting the heating using an etching machine (Lam 2300 MWS), manufactured by Lam Research Corporation, in an O₂/N₂ mixed gas atmosphere at 290° C. under a pressure lower than atmospheric pressure for 15 minutes.

### Comparative Example 2

Observation of micro-phase-separated structure was conducted in the same manner as in Comparative Example 1, except for conducting the heating at a temperature of 270° C. for 15 minutes instead of conducting the heating at a heating temperature of 290° C.

### Comparative Example 3

Observation of micro-phase-separated structure was conducted in the same manner as in Comparative Example 1, except for conducting the heating in an N₂ atmosphere instead of conducting the heating in an air atmosphere.

(Checking the Block Copolymer Orientation)

The orientation was checked with respect to the block copolymers prepared in Examples 2 to 13 and Comparative Examples 1 to 3 above. The results are shown in Table 1, and examples of the results of the observation under an electron microscope are shown in FIG. 3.

(Checking the Block Copolymer Orientation-2)

The orientation was checked with respect to the block copolymers prepared in Examples 14 to 32 above. The results are shown in Table 2.

TABLE 1

| | Underlayer | | | | | Pattern |
|---|---|---|---|---|---|---|
| | film-forming | Atmosphere | | Heating | Heating | orientation |
| | composition | conditions | Pressure | temperature | time | result |
| Example 2 | Polymer 1 | N₂/O₂ | 760 mTorr | 290° C. | 15 min | Vertical |
| | | | | | | orientation |
| Example 3 | Polymer 2 | N₂/O₂ | 760 mTorr | 290° C. | 15 min | Vertical |
| | | | | | | orientation |
| Example 4 | Polymer 3 | N₂/O₂ | 760 mTorr | 290° C. | 15 min | Vertical |
| | | | | | | orientation |
| Example 5 | Polymer 4 | N₂/O₂ | 760 mTorr | 290° C. | 15 min | Vertical |
| | | | | | | orientation |
| Example 6 | Polymer 1 | N₂ | 760 mTorr | 290° C. | 15 min | Vertical |
| | | | | | | orientation |
| Example 7 | Polymer 1 | O₂ | 760 mTorr | 290° C. | 15 min | Vertical |
| | | | | | | orientation |
| Example 8 | Polymer 1 | N₂ | 760 mTorr | 270° C. | 15 min | Vertical |
| | | | | | | orientation |
| Example 9 | Polymer 1 | N₂ | 760 mTorr | 300° C. | 15 min | Vertical |
| | | | | | | orientation |
| Example 10 | Polymer 1 | N₂ | 50 mTorr | 290° C. | 15 min | Vertical |
| | | | | | | orientation |
| Example 11 | Polymer 1 | N₂ | 10000 mTorr | 290° C. | 15 min | Vertical |
| | | | | | | orientation |
| Example 12 | Polymer 1 | N₂ | 760 mTorr | 300° C. | 5 min | Vertical |
| | | | | | | orientation |
| Example 13 | Polymer 1 | N₂ | 760 mTorr | 300° C. | 3 min | Vertical |
| | | | | | | orientation |
| Comparative | Polymer 1 | Air | Atmospheric | 290° C. | 15 min | Defective |
| Example 1 | | | pressure | | | orientation |
| Comparative | Polymer 1 | Air | Atmospheric | 270° C. | 15 min | Defective |
| Example 2 | | | pressure | | | orientation |
| Comparative | Polymer 1 | N₂ | Atmospheric | 290° C. | 15 min | Defective |
| Example 3 | | | pressure | | | orientation |

TABLE 2

| | Block | Underlayer | | | | Pattern |
|---|---|---|---|---|---|---|
| | copolymer forming | film-forming | | Heating | Heating | orientation |
| | composition | composition | Pressure | temperature | time | result |
| Example 14 | Block copolymer 1 | Polymer 1 | 760 mTorr | 290° C. | 15 min | Vertical |
| | | | | | | orientation |
| Example 15 | Block copolymer 1 | Polymer 2 | 760 mTorr | 290° C. | 15 min | Vertical |
| | | | | | | orientation |
| Example 16 | Block copolymer 1 | Polymer 3 | 760 mTorr | 290° C. | 15 min | Vertical |
| | | | | | | orientation |
| Example 17 | Block copolymer 1 | Polymer 4 | 760 mTorr | 290° C. | 15 min | Vertical |
| | | | | | | orientation |
| Example 18 | Block copolymer 1 | Polymer 5 | 760 mTorr | 290° C. | 15 min | Vertical |
| | | | | | | orientation |
| Example 19 | Block copolymer 1 | Polymer 6 | 760 mTorr | 290° C. | 15 min | Vertical |
| | | | | | | orientation |
| Example 20 | Block copolymer 1 | Polymer 7 | 760 mTorr | 290° C. | 15 min | Vertical |
| | | | | | | orientation |
| Example 21 | Block copolymer 1 | Polymer 8 | 760 mTorr | 290° C. | 15 min | Vertical |
| | | | | | | orientation |
| Example 22 | Block copolymer 1 | Polymer 1 | 760 mTorr | 240° C. | 15 min | Vertical |
| | | | | | | orientation |
| Example 23 | Block copolymer 1 | Polymer 1 | 760 mTorr | 260° C. | 15 min | Vertical |
| | | | | | | orientation |
| Example 24 | Block copolymer 1 | Polymer 1 | 760 mTorr | 270° C. | 15 min | Vertical |
| | | | | | | orientation |
| Example 25 | Block copolymer 1 | Polymer 1 | 760 mTorr | 300° C. | 15 min | Vertical |
| | | | | | | orientation |
| Example 26 | Block copolymer 1 | Polymer 1 | 760 mTorr | 320° C. | 5 min | Vertical |
| | | | | | | orientation |
| Example 27 | Block copolymer 1 | Polymer 1 | 250 mTorr | 290° C. | 15 min | Vertical |
| | | | | | | orientation |
| Example 28 | Block copolymer 1 | Polymer 1 | 5000 mTorr | 290° C. | 15 min | Vertical |
| | | | | | | orientation |
| Example 29 | Block copolymer 2 | Polymer 1 | 760 mTorr | 290° C. | 15 min | Vertical |
| | | | | | | orientation |
| Example 30 | Block copolymer 3 | Polymer 1 | 760 mTorr | 290° C. | 15 min | Vertical |
| | | | | | | orientation |
| Example 31 | Block copolymer 4 | Polymer 1 | 760 mTorr | 290° C. | 15 min | Vertical |
| | | | | | | orientation |
| Example 32 | Block copolymer 1 | Brush polymer | 760 mTorr | 290° C. | 15 min | Vertical |
| | | | | | | orientation |

As can be seen from Tables 1 and 2, by the method for inducing micro-phase separation by heating under a pressure lower than atmospheric pressure according to the present invention, vertical orientation of a block copolymer, particularly a PS-b-PMMA block copolymer, can be induced in a temperature range capable of causing directed self-assembly, preferably in an elevated temperature range (270° C. or higher).

### INDUSTRIAL APPLICABILITY

By the present invention, a micro-phase-separated structure of a layer comprising a block copolymer on the entire surface of the applied film can be induced vertically with respect to a substrate without causing defective orientation of micro-phase separation of the block copolymer, and thus the present invention is extremely advantageous from an industrial point of view.

The entire disclosure of Japanese Patent Application No. 2020-091721 (filing date: May 26, 2020) and Japanese Patent Application No. 2020-133320 (filing date: Aug. 5, 2020) are incorporated by reference into the present specification.

All the documents, patent applications, and technical standards mentioned in the present specification are incorporated hereinto by reference as in the same extent that each of the documents, patent applications, and technical standards is specifically and individually stated to be incorporated hereinto by reference.

1. A vertically phase-separated layer of a block copolymer formed by heating the block copolymer at a temperature capable of causing directed self-assembly under a pressure lower than atmospheric pressure.

2. The layer of the block copolymer according to claim 1, wherein the block copolymer is PS-b-PMMA.

3. The vertically phase-separated layer of a block copolymer according to claim 1, wherein the vertically phase-separated layer comprises a cylinder shape portion.

4. The vertically phase-separated layer of a block copolymer according to claim 3, wherein the cylinder shape portion comprises PMMA.

5. The vertically phase-separated layer of a block copolymer according to claim 1, wherein the heating temperature is 270° C. or higher.

6. The vertically phase-separated layer of a block copolymer according to claim 1, which further has a neutralizing layer for neutralizing the surface energy of the block copolymer under the layer of the block copolymer.

7. The vertically phase-separated layer of a block copolymer according to claim 6, wherein the neutralizing layer comprises a polymer having an aromatic compound-derived unit structure.

8. The vertically phase-separated layer of a block copolymer according to claim 7, wherein the polymer in the neutralizing layer contains the aromatic compound-derived unit structure in a proportion of 50% by mole or more.

9. The vertically phase-separated layer of a block copolymer according to claim 6, wherein the neutralizing layer comprises a polymer having a unit structure comprising an aliphatic polycyclic structure of an aliphatic polycyclic compound in a principal chain.

10. The vertically phase-separated layer of a block copolymer according to claim 6, wherein the neutralizing layer comprises a polysiloxane.

11. The vertically phase-separated layer of a block copolymer according to claim 6, wherein the neutralizing layer comprises a polymer having a reactive substituent at a terminal thereof.

12. The vertically phase-separated layer of a block copolymer according to claim 1, which is formed above a substrate.

13. A method for producing a vertically phase-separated layer of a block copolymer, comprising the steps of:
forming a block copolymer layer above a substrate; and then
heating the substrate under a pressure lower than atmospheric pressure.

14. A method for producing a semiconductor device, comprising the steps of:
forming a block copolymer layer above a substrate;
heating the substrate under a pressure lower than atmospheric pressure;
subjecting the vertically phase-separated layer of a block copolymer to etching; and
subjecting the substrate to etching.
